(19) United States
(12) Patent Application Publication
(10) Pub. No.: US 2011/0139225 A1
(43) Pub. Date: Jun. 16, 2011

(54) SHAPED PHOTOVOLTAIC MODULE

(75) Inventor: PHILIP L. BOYDELL, Challex (FR)

(73) Assignee: E. I. DU PONT DE NEMOURS AND COMPANY, Wilmington, DE (US)

(21) Appl. No.: 12/813,569

(22) Filed: Jun. 11, 2010

Related U.S. Application Data
(60) Provisional application No. 61/219,456, filed on Jun. 23, 2009.

(51) Int. Cl. H01L 31/048; H01L 31/02; H01L 31/042; H01L 31/18

(52) U.S. Cl. 136/251; 136/259; 136/244; 156/221; 156/196

(57) ABSTRACT

A photovoltaic module including a frontsheet, a front encapsulant layer, a formable photoactive cell layer, a support layer, and a backside mounting surface. The formable photoactive cell layer includes a flexible substrate and at least a first photoactive cell including a photoactive surface. An orientation of the photoactive surface is different than an orientation of the backside mounting surface.

A formable photoactive cell layer including a flexible substrate and an array of photoactive cells. The photoactive cells are spaced apart to form both a photoactive area and a non-photoactive area of the formable photoactive cell layer. The non-photoactive area is sufficiently large to allow the flexible substrate to be shaped to form the formable photoactive cell layer into a non-planar structure.

### BACKGROUND INFORMATION

1. Field of the Disclosure

This invention relates to photovoltaic modules and cells.

2. Description of the Related Art

Photovoltaic cells, sometimes called solar cells or photoactive cells, can convert light, such as sunlight, into electrical energy. Photoactive cells can be electrically connected together in series and/or in parallel to create a photovoltaic module. In general, the module includes an array of photoactive cells that are connected in series by connecting the anode of one cell with the cathode of the next cell. A set of cells electrically connected in this manner is known as a “string”. Typically, two or more strings are connected in electrical series or in parallel in the construction of a module.

The electrical output of a photovoltaic module increases as the intensity of the light falling upon it increases. A typical module includes an array of photoactive cells, where the photoactive surfaces of the cells are coplanar with the surface plane of the module. The highest electrical output from such modules is obtained when the incident light is perpendicular to the surface plane of the module. In general the cells are arranged as close together as possible in order to maximize the power output of the module per unit area.

It is possible to construct a system in which the module moves in such a way that the surface plane of the module is constantly perpendicular to the incident light as the incident light from the sun changes angles, but in many situations (especially where modules are mounted on buildings or in regions with relatively little direct light) this is not practical, forbidden or too expensive, and the modules are fixed to a building or a ground mounted stand and do not move.

In the case of ground mounting, it is often the case that the photovoltaic module orientation and tilt angle are chosen to give the highest electrical output over a year of service based on the changing path of the sun relative to the module over the course of a year.

In the case of building mounting, such as on a flat or pitched rooftop or a facade, the orientation and tilt angle of the module is generally chosen according to architectural considerations, including, for example, aesthetics, cost of the mounting system, static load, and wind load. On a facade, modules must generally be mounted vertically. In California, for example, vertically mounting a module results in a reduction of the power output of the module by 43% compared to a module mounted at the optimum tilt angle of 38° to the horizontal. Even on a flat rooftop, modules sometimes need to be mounted almost parallel to the roof at close to a 0° angle to the horizontal because of the dynamic load that would be generated during high wind conditions when modules are mounted at an angle from the horizontal. On a German rooftop, a horizontally mounted module has a power output that is 15% less than the output of a module mounted at an optimum tilt angle of 37° to the horizontal. On a pitched roof, the roof pitch might be closer to the optimum tilt angle for power generation but often the orientation is not in the optimum direction (in the Northern hemisphere, approximately due South).

Moreover, as photovoltaic generated electricity is becoming a more important source of energy, there remains a need to have photovoltaic modules that can be efficiently mounted in a wide variety of shapes and on a wide variety of structures, wherein the orientation of the photoactive surfaces of the module and the surface on which the module is mounted are not the same.

### BRIEF DESCRIPTION OF THE DRAWINGS

The invention is illustrated by way of example and not limitation in the accompanying figures.

FIG. 1 is a plan view illustration of one embodiment of a formable photoactive cell layer.

FIG. 2 is a plan view illustration of another embodiment of a formable photoactive cell layer.

FIG. 3 is a cross-sectional view illustration of one embodiment of a shaped photovoltaic module.

FIG. 4 is a cross-sectional view illustration of another embodiment of a shaped photovoltaic module.

FIG. 5 is a cross-sectional view illustration of another embodiment of a shaped photovoltaic module.

FIG. 6 is a cross-sectional view illustration of another embodiment of a shaped photovoltaic module.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

In a first aspect, a photovoltaic module includes a frontsheet, a front encapsulant layer, a formable photoactive cell layer, a support layer, and a backside mounting surface. The formable photoactive cell layer includes a flexible substrate and at least a first photoactive cell including a photoactive surface. An orientation of the photoactive surface is different than an orientation of the backside mounting surface.

For purpose of this disclosure, a photovoltaic cell means an electronic device that converts radiant energy (e.g., light) into an electrical signal. A photovoltaic cell includes a photoactive material that may be an organic or inorganic semiconductor material that is capable of absorbing radiant energy and converting it into electrical energy. The term photovoltaic cell is used herein to include solar cells with all types of photoactive layers including crystalline silicon, amorphous silicon, cadmium telluride, and copper indium gallium selenide (GIGS) photoactive layers.

A photovoltaic module is any electronic device having at least one photovoltaic cell.

The term encapsulant layer refers to a layer of material that is designed to protect the photoactive cells from environmental degradation and mechanical damage. A front encapsulant layer can be located between a photoactive cell layer and the front side of the module (i.e., the side of the module designed to be directed towards the primary source of incoming radiant energy). A back encapsulant layer can be located between a photoactive cell layer and the back side of the module. An encapsulant layer may also surround the edges of the photoactive cell layer, and when both front and rear encapsulant layers are used in a module, they may contact each other and in some cases be viewed as a single layer that surrounds the photoactive cell layer. A front encapsulant layer may require greater optical clarity than a rear encapsulant layer to allow transmission of radiant energy into the module.

In one embodiment of the first aspect, the photovoltaic module includes an array of photoactive cells, including an array of photoactive surfaces, and each photoactive surface has an orientation. In a more specific embodiment, the orientation of each photoactive surface in the array of photoactive surfaces is the same. Use of the term array, herein, means an arrangement of multiple photoactive cells (i.e., at least two). Typically, an array includes multiple cells in an orderly arrangement of columns and rows, but an array need not be orderly, and need not have columns and rows.

In another embodiment of the first aspect, the photovoltaic module includes a second photoactive cell. The second photoactive cell includes a photoactive surface, and an orientation of the photoactive surface of the second photoactive cell is different than an orientation of the photoactive surface of the first photoactive cell.

In still another embodiment of the first aspect, the photovoltaic module includes an array of photoactive cells, including an array of photoactive surfaces, in which each photoactive surface has an orientation, and the flexible substrate includes an electrically insulating material. In a more specific embodiment, the flexible substrate further includes conductive traces that electrically connect the array of photoactive cells.

In a second aspect, a formable photoactive cell layer includes a flexible substrate and an array of photoactive cells. The photoactive cells are spaced apart to form both a photoactive area and a non-photoactive area of the formable photoactive cell layer. The non-photoactive area is sufficiently large to allow the flexible substrate to be shaped to form the formable photoactive cell layer into a non-planar structure.

In one embodiment of the second aspect, the ratio of the photoactive area to the non-photoactive area is less than about 3:1. In a more specific embodiment, the ratio of the photoactive area to the non-photoactive area is less than about 2:1. In a still more specific embodiment, the ratio of the photoactive area to the non-photoactive area is about 1:1.

In a third aspect, a photovoltaic module includes a frontsheet, a front encapsulant layer, a formable photoactive cell layer, and a support layer. The formable photoactive cell layer includes a flexible substrate and an array of photoactive cells. The photoactive cells are spaced apart to form both a photoactive area and a non-photoactive area of the formable photoactive cell layer. The non-photoactive area is sufficiently large to allow the flexible substrate to be shaped. The support layer is a non-planar structure, and the formable photoactive cell layer conforms to the non-planar structure of the support layer.

In one embodiment of the third aspect, the non-planar structure is a corrugated structure. In another embodiment of the third aspect, an orientation of all the photoactive cells in the array of photoactive cells is the same.

Many aspects and embodiments have been described above and are merely exemplary and not limiting. After reading this specification, skilled artisans will appreciate that other aspects and embodiments are possible without departing from the scope of the invention.

Other features and benefits of any one or more of the aspects and embodiments will be apparent from the following detailed description, and from the claims.

In one embodiment, a photovoltaic cell includes a layer of a photoactive material such as crystalline or amorphous silicon, and a layer of a charge carrier material. The photoactive layer and charge carrier layer are disposed between a cathode and an anode. When incident light excites the photoactive material, electrons are released. The released electrons are captured in the form of electrical energy within the electric circuit created between the cathode and the anode. The photoactive layer may alternatively be comprised of dye sensitized titania (titanium dioxide) or organic semiconductors. However the highest electrical efficiencies are attained with cells based on crystalline Si. A drawback of crystalline Si cells is that they are flat and brittle. Thin film cells comprised of, for example, amorphous Si or organic semiconductors can be deposited on flexible substrates. Thin film modules are relatively robust when handled, but have lower efficiencies than crystalline Si. Photoactive cells based on crystalline Si have proven to be popular due to their ease of manufacture and their low cost per power output.

FIG. 1 illustrates one embodiment of a formable photoactive cell layer 100 including a plurality of electrically connected photoactive cells 132 on a flexible substrate 130. Use of the term “formable” herein means that an object can be shaped to modify its configuration. Shaping can include bending, stretching, compressing, twisting, molding, and any combination of these or other actions that may modify the configuration of an object. A formable object, such as a cell layer, may be capable of being modified by one or more of these shaping methods, but need not be capable of being shaped by all of these methods. Flexible substrate 130 can be made of a polymeric material, such as a polyimide (PI), a polyethylene terephthalate (PET), a fluoropolymer such as a polyvinyl fluoride (PVF), a polyvinylidene fluoride (PVDF), an ethylene tetrafluorethylene (ETFE), a perfluoroalkoxy vinyl polymer (PFA), an FEP copolymer of tetrafluoroethylene (TFE) and hexafluoropropylene (HFP) or a combination thereof or other suitable material that is electrically insulating, can withstand the processing conditions for forming the formable photoactive cell layer 100, and can be later formed into the desired shape for the module. The photoactive cells 132 form a string of a set of cells connected in series wherein the anode of one cell is electrically connected to the cathode of the next cell by a conductor 134, such as a copper ribbon. The photoactive cells 132 can have the cathode and the anode disposed on opposite faces, or in some embodiments, the anode and the cathode can both be placed on the same side, e.g., on the side away from the incident radiation (“back side contact cells”). Having both sets of electrodes on the same side of the photoactive cells can simplify the electrical connections. The string of photoactive cells 132 is electrically connected to the external electrical connections by a conductor 134 such as a copper ribbon. In one embodiment, rows of photoactive cells 132 are spaced apart based on the desired orientation of the cells in the shaped module to be formed.

In one embodiment, the photoactive cells 132 are spaced apart to form both photoactive areas 136 and non-photoactive areas 138 of the formable photoactive cell layer 100. The photoactive areas 136 include the photoactive cells 132 that respond to incident light to generate electrical energy as described above. The primary function of the non-photoactive areas 138 is to provide areas on the formable photoactive cell layer 100 to shape the flexible substrate 130 into a non-planar shaped structure. In one embodiment, described below, a formable photoactive cell layer may be shaped to conform to the configuration of a support layer. If the photoactive cells 132 are rigid, the non-photoactive area 138 must be sufficiently large to allow the flexible substrate to be shaped without damaging the photoactive cells 132.

In one embodiment, the ratio of the photoactive area 136 to the non-photoactive 138 area is less than about 3:1. In a more specific embodiment, the ratio of the photoactive area 136 to the non-photoactive area 138 is less than about 2:1. In a still more specific embodiment, the ratio of the photoactive area 136 to the non-photoactive area 138 is about 1:1. A formable photoactive cell layer 100 may include rows of photoactive cells 132 forming strips of photoactive area 136 separated by strips of non-photoactive area 138.

The photoactive areas 136 can include portions that do not respond to incident light to form electrical energy and are thus non-photoactive (e.g., the space between photoactive cells 132 in a same row, or areas where electrical charge is transported). Conversely, the non-photoactive areas 138 may include portions that are photoactive (e.g., if the photoactive cells 132 are not rigid, there may be process advantages to forming photoactive cells 132 in the non-photoactive area 138).

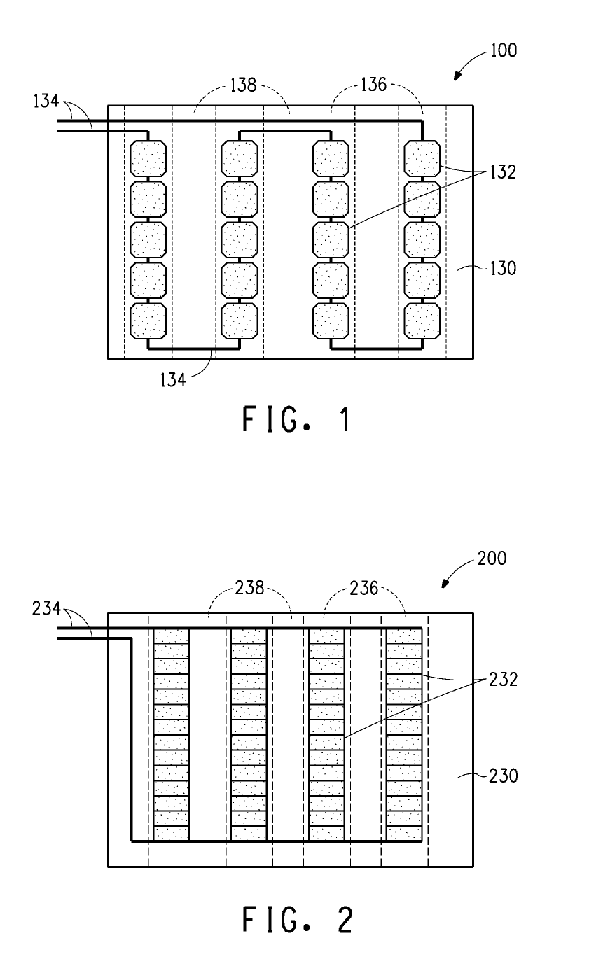

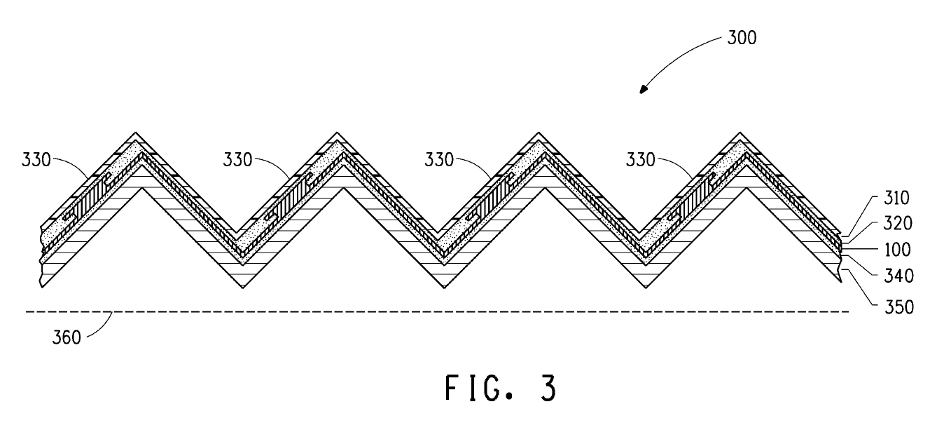

FIG. 2 illustrates another embodiment, of a formable photoactive cell layer 200 prior to forming a shaped structure. The photoactive cells 232 may be formed by a thin film process using monolithic integration of the components of the cells on a flexible substrate 230. The formation of external conductors 234 that transport electrical charge away from the photoactive cells 232 can be simplified. Once again, rows of photoactive cells 232 are spaced apart based on the desired orientation of the cells in the shaped module to be formed. Skilled artisans will appreciate that a variety of arrangements and geometries of photoactive cells may be used based on the desired form and function of the final module.

In one embodiment, the photoactive cells 232 are spaced apart to form both photoactive areas 236 and non-photoactive areas 238 of the formable photoactive cell layer 200. The photoactive areas 236 include the photoactive cells 232 that respond to incident light to generate electrical energy as described above. The primary function of the non-photoactive areas 238 is to provide areas on the formable photoactive cell layer 200 to shape the flexible substrate 230 into a non-planar structure. In one embodiment, described below, a formable photoactive cell layer may be shaped to conform to the configuration of a support layer. If the photoactive cells 232 are rigid, the non-photoactive area 238 must be sufficiently large to allow the flexible substrate to be shaped without damaging the photoactive cells 232.

In one embodiment, the ratio of the photoactive area 236 to the non-photoactive area 238 is less than about 3:1. In a more specific embodiment, the ratio of the photoactive area 236 to the non-photoactive area 238 is less than about 2:1. In a still more specific embodiment, the ratio of the photoactive area 236 to the non-photoactive area 238 is about 1:1. A formable photoactive cell layer 200 may include rows of photoactive cells 232 forming strips of photoactive area 236 separated by strips of non-photoactive area 238.

The photoactive areas 236 can include portions that do not respond to incident light to form electrical energy and are thus non-photoactive (e.g., the space between photoactive cells 232 in a same row, or areas where electrical charge is transported). Conversely, the non-photoactive areas 238 may include portions that are photoactive (e.g., if the photoactive cells 232 are not rigid, there may be process advantages to forming photoactive cells 232 in the non-photoactive area 238).

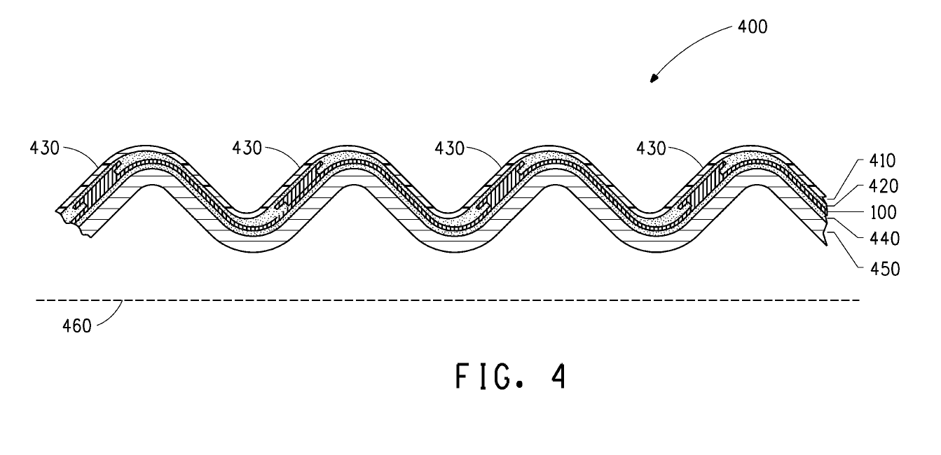

FIG. 3 illustrates one embodiment of a shaped photovoltaic module 300. The module 300 includes a frontsheet 310 formed of a formable light transmitting material that may be rigid or flexible. The function of the frontsheet 310 is to provide a transparent protective layer that will allow incident radiation (e.g., sunlight) into the module 300. The frontsheet 310 may be made of a rigid material, such as a glass, polycarbonate, acrylate polymer such as polymethylmethacrylate material, or a more flexible material, such as a fluoropolymer such as a polyvinyl fluoride (PVF), a polyvinylidene fluoride (PVDF), an ethylene tetrafluorethylene (ETFE), a perfluoroalkoxy vinyl polymer (PFA), an FEP copolymer of tetrafluoroethylene (TFE) and hexafluoropropylene (HFP) or a combination thereof. In general, the frontsheet material may be any material that provides the adequate environmental protection for the module 300 while also providing sufficient transparency to the desired incident radiation. In one embodiment, frontsheet 310 may be a single layer of material, while in other embodiments, frontsheet 310 may include more than one layer of material.

A front encapsulant layer 320 is disposed adjacent to and between the frontsheet 310 and the formable photoactive cell layer 100. The front encapsulant layer 320 is designed to encapsulate and further protect the photoactive cells 132 in the formable photoactive cell layer 100 from environmental degradation and mechanical damage. The front encapsulant layer 320 must have adequate transparency to allow the desired incident radiation to reach the photoactive cells 132. The embodiment illustrated in FIG. 3 is shown with the formable photoactive cell layer 100, but the formable photoactive cell layer may alternatively be any formable photoactive cell layer, including the formable photoactive cell layer shown in FIG. 2.

The front encapsulant layer 320 may comprise one or more copolymers of ethylene with vinyl acetate (EVA), or any unsaturated vinyl monomer. In other embodiments, front encapsulant layer 320 may comprise ionomer. As used herein, the term “ionomer” means and denotes a thermoplastic resin containing both covalent and ionic bonds derived from ethylene copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical Properties And Structural Features Of Surlyn lonomer Resins”, Polyelectrolytes, 1976, C, 177-197.

lonomers useful in the practice of the present invention may be copolymers obtained by the copolymerization of ethylene and an ethylenically unsaturated C₃-C₈ carboxylic acid. In one embodiment, the unsaturated carboxylic acid is either acrylic acid or methacrylic acid. The acid copolymer can include from about 8 wt % to about 20 wt % of the acid, based on the total weight of the copolymer. Ionomers useful as encapsulant layers may comprise from about 12 wt % to about 20 wt % acid, in particular embodiments from about 14 wt % to about 19 wt % acid, and in more particular embodiments from about 15 wt % to about 19 wt % acid.

In some embodiments, front encapsulant layer 320 can include more than one layer of encapsulant material, wherein each layer may include a same or different encapsulant material than the other layer(s).

In some embodiments, aminofunctional coupling agents, such as the one available from the Union Carbide Corporation under the tradename Organofunctional Silane A-1100, which is believed to be gamma-aminopropyltriethoxysilane, may be used to improve bonding of the front encapsulant layer 320 to the frontsheet 310.

In other embodiments, ethylene acid copolymers can be used as encapsulant layer 320, such as ethylene/acrylic acid and ethylene/methacrylic acid copolymers; ethylene copolymers, ethylene/acid terpolymers, such as ethylene/vinyl acetate/acrylic acid polymers, ethylene/(meth)acrylic acid/alkyl(meth)acrylate polymers having 2-12 carbon atoms in the alkyl group, like, ethylene/acrylic acid/butyl acrylate polymers, polyurethanes and polyvinylbuyrate polymers.

In some embodiments, a UV stabilization additive can be included with the front encapsulant material to prevent UV degradation of the encapsulant.

A back encapsulant layer 340 is designed to encapsulate and further protect the photoactive cells 132 in the formable photoactive cell layer 100 from environmental degradation and mechanical damage, and also bonds the formable photoactive cell layer 100 to the support layer 350. The back encapsulant layer 340 can be made of any of the same materials as described above with regard to the front encapsulant layer 320, although in some embodiments, back encapsulant layer 340 may be different than front encapsulant layer 320, since optical clarity is not necessary for back encapsulant layer 340.

The support layer 350 is disposed adjacent to the back encapsulant layer 340. The shape of the support layer 350 defines the angle at which photoactive surfaces 330 are oriented relative to the backside mounting surface 360 of the module 300. The formable photoactive cell layer 100 can be shaped along with the frontsheet 310 and the encapsulant layers 320 and 340 to conform to the shape of the support layer 350. In a specific embodiment, the support layer 350 has a corrugated shape. The support layer 350 is a fixed layer that once mounted to a structure (e.g., a building, not shown), does not move independently of the structure. The backside mounting surface 360 is a surface defined by a plurality of points at which the module 300 may be attached (e.g., to a roof or a frame on the ground). The backside mounting surface 360 may be a physical surface, or it may be defined by a vector plane with a surface normal perpendicular to the vector plane. In one embodiment, the photoactive surfaces 330 are essentially parallel to each other and at an angle of about 45° relative to the backside mounting surface 360 of the module 300. Thus, in this embodiment, a module 300 can be installed on a flat structure approximately parallel to or perpendicular to the horizon, and still have the photoactive surfaces 330 face an advantageous direction relative to the incident radiation (i.e., the path of the sun). In other embodiments (not shown), the support layer 350 can be shaped to provide a variety of orientations of the photoactive surfaces 330 relative to the backside mounting surface 360. In some embodiments (not shown), a module may be mounted on a non-planar surface (e.g., a curved wall, an undulating roof, etc.) such that the backside mounting surface is non-planar. In these embodiments, the module may still be designed such that the photoactive surfaces are advantageously oriented to maximize their exposure to incident radiation. Skilled artisans will appreciate that numerous other arrangements and orientations of photoactive surfaces 330 and support layer 350 within a module are possible.

The dimensions of the photovoltaic modules are typically from 1 to 10 meters in length and from 50 cm to 3 meters in width, depending on the flexibility of the module and the type of photoactive layer used. Rigid modules are typically not longer than 2.5 meters, whereas modules that can be rolled up may have lengths of up to 1 km and widths up to 3 meters. The photoactive surfaces of the module typically have a longer dimension length that is close to the width of the module and a shorter dimension width of from 5 to 25 cm and more preferably from 15 to 20 cm for crystalline silicon cells, and a shorter dimension width of from 1 to 25 cm and more preferably from 5 to 15 cm for thin film solar cells. The non-photoactive surfaces (located between the photoactive surfaces) typically have a length that is similar to the photoactive surfaces, but a width that is equivalent or shorter than the width of the adjoining photoactive surfaces, depending on the angle at which the photoactive surfaces and non-photoactive surfaces are inclined relative to the backside mounting surface. For example, photoactive surfaces are inclined at an angle of 45° relative to the backside mounting surface, the width of the photoactive surfaces will be 0.5 to 1.3 times the width of the adjoining non-photoactive surfaces. Where the photoactive surfaces are inclined at an angle of 30° relative to the backside mounting surface, the width of the photoactive surfaces will be 0.5 to 2 times the width of the adjoining non-photoactive surfaces. The overall thickness of a corrugated module like the module 300 shown in FIG. 3 is typically in the range of 4 to 12 cm, and more typically in the range of 6 to 10 cm.

The photovoltaic module 300 can further include a frame (not shown) to provide additional structural support. The frame can be made from any material that provides adequate rigidity, while minimizing additional weight to the module. Aluminum, or other lightweight metals, rigid polymer, or polymer composite materials can be used.

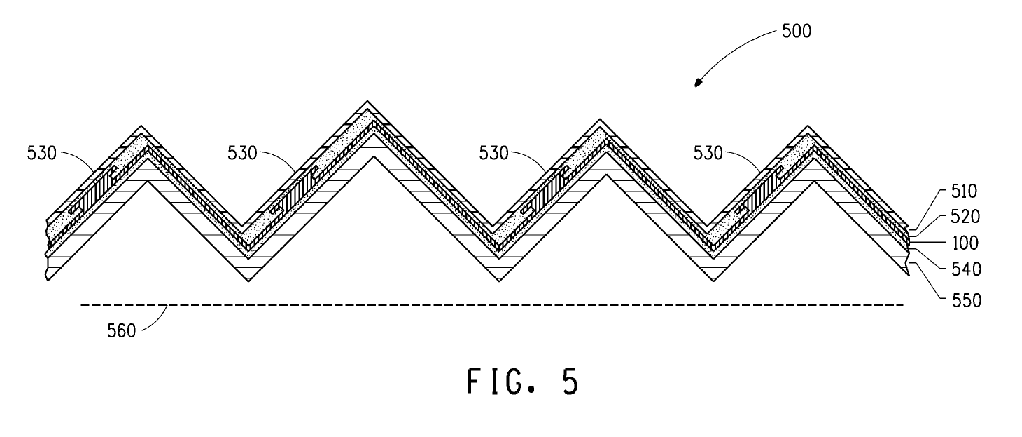

FIG. 4 illustrates another embodiment of a photovoltaic module. The module 400 includes a frontsheet 410 formed of a formable light transmitting material that may be rigid or flexible. The function of the frontsheet 410 and the materials from which frontsheet 410 may be made are the same as those described above for frontsheet 310. In general, the frontsheet material may be any material that provides the adequate environmental protection for the module 400 while also providing sufficient transparency to the desired incident radiation.

A front encapsulant layer 420 is disposed adjacent to and between the frontsheet 410 and the formable photoactive cell layer 100. The front encapsulant layer 420 is designed to encapsulate and further protect the photoactive cells in the formable photoactive cell layer 100 from environmental degradation and mechanical damage. The front encapsulant layer 420 must have adequate transparency to allow the desired incident radiation to reach the photoactive cells. A back encapsulant layer 440 is designed to encapsulate and further protect the photoactive cells in the formable photoactive cell layer 100 from environmental degradation and mechanical damage, and also bonds the formable photoactive cell layer 100 to the support layer 450. The back encapsulant layer 440 and the front encapsulant layer 420 can be made of the same materials as describe above for encapsulant layers 340 and 320, respectively.

The support layer 450 is disposed adjacent to the back encapsulant layer 440. The shape of the support layer 450 defines the angle at which photoactive surfaces 430 are oriented relative to the backside mounting surface 460 of the module 400. The formable photoactive cell layer 100 can be shaped along with the frontsheet 410 and the encapsulant layers 420 and 440 to conform to the shape of the support layer 450. In a specific embodiment, the support layer 450 has a sinusoidal shape. The support layer 450 is a fixed layer that once mounted to a structure (e.g., a building, not shown), does not move independently of the structure. The backside mounting surface 460 is a surface defined by a plurality of points at which the module 400 may be attached (e.g., to a roof or a frame on the ground). The backside mounting surface 460 may be a physical surface, or it may be defined by a vector plane with a surface normal perpendicular to the vector plane. In one embodiment, the photoactive surfaces 430 are essentially parallel to each other and at an angle of about 45° relative to the backside mounting surface 460 of the module 400. Thus, in this embodiment, a module 400 can be installed on a flat structure approximately parallel to the horizon, and still have the photoactive surfaces 430 face an advantageous direction relative to the incident radiation (i.e., the path of the sun). In other embodiments (not shown), the support layer 450 can be shaped to provide a variety of orientations of the photoactive surfaces 430 relative to the backside mounting surface 460. Skilled artisans will appreciate that numerous other arrangements and orientations of photoactive surfaces 430 and support layer 450 within a module are possible.

The photovoltaic module 400 can further include a frame (not shown) to provide additional structural support. The frame can be made from any material that provides adequate rigidity, while minimizing additional weight to the module. Aluminum, or other lightweight metals, rigid polymer, or polymer composite materials can be used.

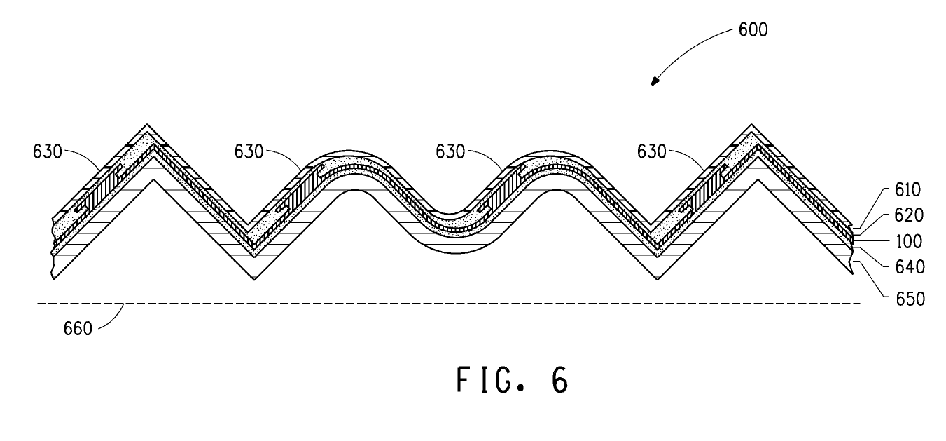

FIG. 5 illustrates another embodiment of a photovoltaic module. The module 500 includes a frontsheet 510 formed of a formable light transmitting material that may be rigid or flexible. The function of the frontsheet 510 and the materials from which frontsheet 510 may be made are the same as those described above for frontsheet 310. In general, the frontsheet material may be any material that provides adequate environmental protection for the module 500 while also providing sufficient transparency to the desired incident radiation.

A front encapsulant layer 520 is disposed adjacent to and between the frontsheet 510 and the formable photoactive cell layer 100. The front encapsulant layer 520 is designed to encapsulate and further protect the photoactive cells in the formable photoactive cell layer 100 from environmental degradation and mechanical damage. The front encapsulant layer 520 must have adequate transparency to allow the desired incident radiation to reach the photoactive cells. A back encapsulant layer 540 is designed to encapsulate and further protect the photoactive cells in the formable photoactive cell layer 100 from environmental degradation and mechanical damage, and also bonds the formable photoactive cell layer 100 to the support layer 550. The back encapsulant layer 540 and the front encapsulant layer 520 can be made of the same materials as describe above for encapsulant layers 340 and 320, respectively.

The support layer 550 is disposed adjacent to the back encapsulant layer 540. The shape of the support layer 550 defines the angle at which photoactive surfaces 530 are oriented relative to the backside mounting surface 560 of the module 500. The formable photoactive cell layer 100 can be shaped along with the frontsheet 510 and the encapsulant layers 520 and 540 to conform to the shape of the support layer 550. In a specific embodiment, the support layer 550 has a corrugated shape where the heights of the peaks are varied across an array of photoactive cells. The resulting module 500 would be able to accommodate photoactive cells of multiple sizes, or could provide an array of photoactive surfaces 530 that are at multiple orientations. Skilled artisans will appreciate that numerous other arrangements and orientations of photoactive surfaces 530 and support layer 550 within a module are possible. The support layer 550 is a fixed layer that once mounted to a structure (e.g., a building, not shown), does not move independently of the structure. The backside mounting surface 560 is a surface defined by a plurality of points at which the module 500 may be attached (e.g., to a roof or a frame on the ground). The backside mounting surface 560 may be a physical surface, or it may be defined by a vector plane with a surface normal perpendicular to the vector plane. In one embodiment, the photoactive surfaces 530 are essentially parallel to each other and at an angle of about 45° relative to the backside mounting surface 560 of the module 500. Thus, in this embodiment, a module 500 can be installed on a flat structure approximately parallel to the horizon, and still have the photoactive surfaces 530 face an advantageous direction relative to the incident radiation (i.e., the path of the sun).

The photovoltaic module 500 can further include a frame (not shown) to provide additional structural support. The frame can be made from any material that provides adequate rigidity, while minimizing additional weight to the module. Aluminum, or other lightweight metals, rigid polymer, or polymer composite materials can be used.

FIG. 6 illustrates another embodiment of a photovoltaic module. The module 600 includes a frontsheet 610 formed of a formable light transmitting material that may be rigid or flexible. The function of the frontsheet 610 and the materials from which frontsheet 610 may be made are the same as those described above for frontsheet 310. In general, the frontsheet material may be any material that provides adequate environmental protection for the module 600 while also providing sufficient transparency to the desired incident radiation.

A front encapsulant layer 620 is disposed adjacent to and between the frontsheet 610 and the formable photoactive cell layer 100. The front encapsulant layer 620 is designed to encapsulate and further protect the photoactive cells in the formable photoactive cell layer 100 from environmental degradation and mechanical damage. The front encapsulant layer 620 must have adequate transparency to allow the desired incident radiation to reach the photoactive cells. A back encapsulant layer 640 is designed to encapsulate and further protect the photoactive cells in the formable photoactive cell layer 100 from environmental degradation and mechanical damage, and also bonds the formable photoactive cell layer 100 to the support layer 650. The back encapsulant layer 640 and the front encapsulant layer 620 can be made of the same materials as describe above for encapsulant layers 340 and 320, respectively.

The support layer 650 is disposed adjacent to the back encapsulant layer 640. The shape of the support layer 650 defines the angle at which photoactive surfaces 630 are oriented relative to the backside mounting surface 660 of the module 600. The formable photoactive cell layer 100 can be shaped along with the frontsheet 610 and the encapsulant layers 620 and 640 to conform to the shape of the support layer 650. In a specific embodiment, the support layer 650 has a shape that is a mixture of corrugated and sinusoidal shapes (e.g., a blend of the shapes of support layers 350 and 450 above). The support layer 650 is a fixed layer that once mounted to a structure (e.g., a building, not shown), does not move independently of the structure. The backside mounting surface 660 is a surface defined by a plurality of points at which the module 600 may be attached (e.g., to a roof or a frame on the ground). The backside mounting surface 660 may be a physical surface, or it may be defined by a vector plane with a surface normal perpendicular to the vector plane. In one embodiment, the photoactive surfaces 630 are essentially parallel to each other and at an angle of about 45° relative to the backside mounting surface 660 of the module 600. Thus, in this embodiment, a module 600 can be installed on a flat structure approximately parallel to the horizon, and still have the photoactive surfaces 630 face an advantageous direction relative to the incident radiation (i.e., the path of the sun). In other embodiments (not shown), the support layer 650 can be shaped to provide a variety of orientations of the photoactive surfaces 630 relative to the backside mounting surface 660. Skilled artisans will appreciate that numerous other arrangements and orientations of photoactive surfaces 630 and support layer 650 within a module are possible.

The photovoltaic module 600 can further include a frame (not shown) to provide additional structural support. The frame can be made from any material that provides adequate rigidity, while minimizing additional weight to the module. Aluminum, or other lightweight metals, rigid polymer, or polymer composite materials can be used.

In one embodiment, a process for assembling a photovoltaic module can include: (1) forming conductive traces (e.g., copper ribbons) and electrical contacts on a flexible substrate; (2) forming at least a first photoactive cell on the flexible substrate to form a photoactive layer; (3) electrically connecting the at least first photoactive cell to the conductive traces via the electrical contacts; (4) forming an encapsulation layer on at least a first side of the photoactive layer; (5) providing a protective layer (i.e., frontsheet) on a front side of the photoactive layer; (6) providing a protective layer on a back side of the photoactive layer; (7) laminating the photoactive layer, the encapsulation layer(s) and the protective layers; (8) attaching the laminated layers to a support layer; (9) attaching a support frame; and (10) providing external electrical contacts to electrically connect the module to an external control circuit.

Step (3) of electrical connecting may be performed by soldering. Examples of soldering techniques include hot air, contact, laser and induction soldering. Soldering is carried out above, typically 20 to 50° C. above the liquidus point of the solder and is aided by the use of a flux. Whilst leaded solder is still widely used, other solder materials can also be used. In another embodiment, the electrical connecting may be performed by use of a conductive adhesive. In still another embodiment, the electrical connecting may be performed by making pure contact of conductive traces which are kept in contact by mechanical pressure applied in lamination step (7).

In lamination step (7), the layers are heated to allow the encapsulant to flow around the cells and bond to the frontsheet and the photoactive cells, and if necessary further heated to effect crosslinking of the encapsulant. The resulting ‘laminate’ is then sealed around the edges and ends of the copper ribbons. The lamination is typically performed at elevated temperatures of, for example, 100 to 180° C., in particular 120 to 170° C. and more particularly 130 to 150° C. During the lamination process mechanical pressure is applied; the atmospheric pressure in the laminator chamber is typically 300 to 1200 mbar, in particular 500 to 1000 mbar and more particularly 600 to 900 mbar.

The laminate is then shaped and formed to fit the contours of the support layer to which it is attached in step (8). Provided that the materials of the laminate are sufficiently thermoplastic, the shaping of the laminate may be performed under application of heat, for example, by thermal folding. In an embodiment, the shaping may also be done by simple mechanical means if the materials involved have a sufficient degree of plasticity at ambient temperature. In a further embodiment, shaping of the laminate may be performed simply by sagging of the laminate into a preformed shape. In still a further embodiment, shaping of the laminate may be performed by stamping. In another embodiment, the shaping of the laminate happens during the lamination step itself; to this end, the laminate materials may be placed on or into a preformed shape and the lamination is performed directly to the desired shape of the laminate.

The support layer is designed to fit the contour of the structure that is to support the module. The shape of the support layer ensures that upon installation the photoactive surfaces are facing in a desired direction relative to the incident radiation.

In an alternative embodiment of this process, a formable support layer may be used and can be attached to the other module layers before lamination, and a protective layer on the back side of the photoactive layer is optional. In this embodiment, the support layer is bonded to the other layers during the lamination step, and then the entire assembly is shaped.

In some embodiments, there is an optimum orientation and tilt angle for the photoactive surfaces in a module, regardless of the orientation and tilt of the surface upon which it is mounted.

Note that not all of the activities described above are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, references to values stated in ranges include each and every value within that range.

### EXAMPLES

A sheet of ethylene vinyl acetate (EVA) back encapsulant, commercially available from Etimex (Dietenheim, DE) under the trademark VISTASOLAR (Type 486.10 FC), having a thickness of 450 micron was superposed on an aluminum sheet having a thickness of 2 mm. Four photoactive cell arrays were placed on top of the sheet of EVA and arranged substantially parallel to the other cell arrays where each cell array was separated by about 24 cm from its neighboring array or arrays. Each array consisted of 1×6 standard photoactive cells, commercially available from Photovoltech (Tiene, BE) under the name MAXIS.

The photoactive cells were strung together with an automatic stringing machine from EcoProgetti using copper ribbon, commercially available from Ulbrich (North Haven, US) in combination with a halogen-free, non rosin organic flux, commercially available from Kester (Itasca,

US) under the name Kester 952S. The copper ribbon was held in place by rolls that moved along the busbar and soldering was done by hot air at 400° C. A second, third and fourth array of 1×6 standard photoactive cells were placed on top of the sheet of EVA so as to separate each array from its neighboring array. A sheet of ethylene vinyl acetate (EVA) front encapsulant, commercially available from Etimex (Dietenheim, DE) under the trademark VISTASOLAR (Type 486.10 FC), having a thickness of 450 micron was superposed on the arrays of photovoltaic cells.

A sheet of ethylene tetrafluoroethylene (ETFE) front sheet, commercially available from DuPont de Nemours (Wilmington, US) under the trademark Teflon CLZ500 was superposed on the sheet of EVA front encapsulant.

The resulting stack having the following structure from bottom to top, Aluminum/EVA/Cells/EVA/ETFE, was inserted into a 3S laminating machine for lamination. The lamination was performed at a temperature of 140° C. and an atmospheric pressure of 600 mbar in the laminating machine for an overall cycle time of 19 minutes.

The resulting essentially flat laminate was then bent into a non-planar shape using an industrial mechanical folding machine so as to give the photoactive cells of the arrays an essentially identical orientation that is different from the orientation of the non-photoactive surface devoid of photoactive cells.

What is claimed is:

1. A photovoltaic module comprising a frontsheet, a front encapsulant layer, a formable photoactive cell layer, a support layer, and a backside mounting surface, wherein:
the formable photoactive cell layer comprises a flexible substrate and at least a first photoactive cell comprising a photoactive surface; and
an orientation of the photoactive surface is different than an orientation of the backside mounting surface.

2. The photovoltaic module of claim 1, wherein the at least a first photoactive cell comprises an array of photoactive cells comprising an array of photoactive surfaces, wherein each photoactive surface has an orientation.

3. The photovoltaic module of claim 2, wherein the orientation of each photoactive surface in the array of photoactive surfaces is the same.

4. The photovoltaic module of claim 1, further comprising a second photoactive cell, wherein:
the second photoactive cell comprises a photoactive surface; and
an orientation of the photoactive surface of the second photoactive cell is different than an orientation of the photoactive surface of the first photoactive cell.

5. The photovoltaic module of claim 2, wherein the flexible substrate comprises an electrically insulating material.

6. The photovoltaic module of claim 5, wherein the flexible substrate further comprises conductive traces that electrically connect the array of photoactive cells.

7. A formable photoactive cell layer comprising a flexible substrate and an array of photoactive cells, wherein:
the photoactive cells are spaced apart to form both a photoactive area and a non-photoactive area of the formable photoactive cell layer; and
the non-photoactive area is sufficiently large to allow the flexible substrate to be shaped to form the formable photoactive cell layer into a non-planar structure.

8. The formable photoactive cell layer of claim 7, wherein the ratio of the photoactive area to the non-photoactive area is less than about 3:1.

9. The formable photoactive cell layer of claim 8, wherein the ratio of the photoactive area to the non-photoactive area is less than about 2:1.

10. The formable photoactive cell layer of claim 9, wherein the ratio of the photoactive area to the non-photoactive area is about 1:1.

11. A photovoltaic module comprising a frontsheet, a front encapsulant layer, a formable photoactive cell layer, and a support layer, wherein:
the formable photoactive cell layer comprises a flexible substrate and an array of photoactive cells;
the photoactive cells are spaced apart to form both a photoactive area and a non-photoactive area of the formable photoactive cell layer;
the non-photoactive area is sufficiently large to allow the flexible substrate to be shaped;
the support layer is a non-planar structure; and
the formable photoactive cell layer conforms to the non-planar structure of the support layer.

12. A process for assembling a photovoltaic module including the steps:
forming conductive traces and electrical contacts on a flexible substrate;
forming at least a first photoactive cell on the flexible substrate to form a formable photoactive cell layer, said formable photoactive cell layer having a photoactive area containing said first photoactive cell and a non-photoactive area wherein the non-photoactive area is sufficiently large to allow the flexible substrate to be shaped;
electrically connecting the at least first photoactive cell to the conductive traces via the electrical contacts;
forming an encapsulation layer on at least a first side of the formable photoactive cell layer;
providing a protective layer on a front side of the formable photoactive cell layer;
providing a protective layer on a back side of the formable photoactive cell layer;
laminating the formable photoactive cell layer, the encapsulation layer and the protective layers;
shaping formable photoactive cell layer, the encapsulation layer and the protective layers such that the photoactive area is at an angle to the non-photoactive area; and
providing external electrical contacts to electrically connect the module to an external control circuit.

13. The process of claim 12, comprising the additional steps of:
providing a contoured support layer;
shaping the laminated formable photoactive cell layer, encapsulation layer and protective layers to fit the contours of the support layer; and
attaching the laminated formable photoactive cell layer, encapsulation layer and protective layers to the support layer.
